(19) United States
(12) Patent Application Publication
(10) Pub. No.: US 2004/0023132 A1
(43) Pub. Date: Feb. 5, 2004

(54) Photomask, pattern production method, and semiconductor device

(75) Inventor: Hisashi Akiyama, Sakata-shi (JP)

Correspondence Address: HOGAN & HARTSON L.L.P., 500 S. GRAND AVENUE, SUITE 1900, LOS ANGELES, CA, 90071-2611, US

(73) Assignee: SEIKO EPSON CORPORATION

(21) Appl. No.: 10/454,364

(22) Filed: Jun. 3, 2003

(30) Foreign Application Priority Data
Jun. 5, 2002 (JP) 2002-164914

(51) Int. Cl. G03F 1/00; H01L 23/58; B32B 3/10

(52) U.S. Cl. 430/5; 257/798; 428/195.1

(57) ABSTRACT

A photomask for transferring a pattern includes a predetermined line arranged in a pattern and a bar-shaped auxiliary pattern for correcting line degeneration disposed at least near an end of the predetermined line or near an outside corner of the predetermined line and arranged in an oblique direction that differs from the direction of the predetermined line.

### BACKGROUND OF THE INVENTION

### Field of the Invention

The present invention relates to a photomask, a method for producing a photomask, and a semiconductor device that at least requires correction of line degeneration during exposure of a miniaturized integrated circuit pattern.

In recent years we have witnessed remarkable advances in the scale of circuit integration and in the miniaturization of semiconductor elements. These advances have been accompanied by the use of a plurality of complex and micropatterned photomasks during a photolithographic process for fabricating semiconductor elements to form circuit patterns. Included among such photomasks are phase shift masks, optical proximity correction masks and other masks used for overcoming the limits of resolution. Optical proximity correction masks in particular include two layers, one an opaque layer and the other a transmissive layer. Optical proximity correction masks are inexpensive and provide superior throughput.

An optical proximity correction mask has the advantage of preventing the degeneration of lines in patterns caused by optical proximity effects during pattern exposure. This mask includes auxiliary (correction) patterns for optical proximity correction that distorts a mask pattern in the direction opposite the direction of curvature of the lens used during exposure. Among these auxiliary patterns is a type called an assist bar, a fine line bar disposed parallel to the direction in which a pattern line extends.

An assist bar is a bar-shaped pattern arranged parallel to but separated by a prescribed distance from a line that follows the X or Y direction within a fine mask pattern of a photomask. By providing an assist bar, optical proximity is further corrected such that the degeneration of lines in the width direction is improved compared to exposure with an ordinary mask pattern.

However, optical proximity correction masks of the prior art have areas where the degeneration of lines cannot be effectively reduced. In particular, the ends of lines and/or corner areas where the direction of a line changes cannot be effectively corrected, and variations exceeding the expected values of the main data on the reticle tend to occur.

The present invention, which takes the aforementioned situation into consideration, is intended to provide a photomask, a method for producing a pattern, and a semiconductor element that readily reduces the degeneration of lines in miniaturized exposure patterns, thereby improving reliability.

### SUMMARY OF THE INVENTION

According to one aspect of the present invention, a photomask for transferring a pattern for forming an element and an integrated circuit to a substrate includes a predetermined line arranged in the pattern, and a bar-shaped auxiliary pattern for correcting line degeneration disposed at least near the outside corner of the predetermined line where the direction changes and arranged in an oblique direction that differs from the direction of the predetermined line.

According to a photomask of the aforementioned present invention, a bar-shaped auxiliary pattern arranged in an oblique direction effectively functions to correct at least the degeneration of the ends of the predetermined line and of the outside corner where the predetermined line direction changes, in an actual exposure pattern.

As a more preferable embodiment of the present invention, a photomask for transferring a pattern for forming an element and an integrated circuit to a substrate includes a predetermined line running in the X direction or Y direction in the pattern; a bar-shaped first auxiliary pattern for correcting line degeneration, separated by a prescribed distance from the predetermined line and parallel to the X direction or Y direction; and a bar-shaped second auxiliary pattern for correcting line degeneration, oblique to both the X and Y directions, disposed near the end of the predetermined line or near an outside corner where the direction of the predetermined line changes.

According to a photomask of the aforementioned present invention, disposing the first and second auxiliary patterns enables the achievement of high reliability in the correction of line width, length, and corner degeneration.

The photomask according to the present invention, includes the first auxiliary pattern or the second auxiliary pattern being a bar shape of a prescribed length located in the direction of an angle of approximately 45 degrees with respect to both the X and the Y directions. In other words, the state of correction is made desirable for all corners.

A method for producing the mask pattern according to the present invention in accordance with the formation of an element and an integrated circuit on a substrate includes forming a predetermined line running in the X direction or Y direction in the pattern and disposing a bar-shaped pattern as a pattern for optical proximity effects correction in the direction of a specific angle with respect to both the X and the Y directions and, in response to information for the end of the predetermined line or a corner where the direction of the predetermined line changes, in a region separated a prescribed distance from the corner.

According to a method of producing a mask pattern of the present invention, a specific bar-shaped pattern is automatically disposed in a region separated from a corner by a prescribed distance. Hence, mask pattern production is expeditiously achieved with a small amount of information.

The method for producing a mask pattern according to claim 5 of the present invention, belonging to claim 4, further disposing a bar-shaped pattern that serves as a pattern for correcting optical proximity effects in the mask pattern such that the bar-shaped pattern is parallel to the X direction or the Y direction, depending on information for the predetermined line, but separated by a prescribed distance from the line.

According to a method of producing a mask pattern of the present invention, a specific bar-shaped pattern is automatically disposed parallel to a line and, furthermore, in a region separated from a corner by a prescribed distance. Hence, mask pattern production is expeditiously achieved with a small amount of information.

A semiconductor device according to the present invention includes the formation of an element and an integrated circuit pattern on a substrate using a photomask. The corner shape is improved with respect to miniaturized pattern sizes, and contributes particularly to improvement in the reliability of contact patterns for wiring.

### BRIEF DESCRIPTION OF THE DRAWINGS

FIGS. 1 (a) & (b) are schematic block diagrams showing the major parts of a photomask according to the basic embodiment of the present invention.

FIG. 2 is a plan view showing the major parts of a photomask according to a preferred embodiment of the present invention.

FIG. 3 is a plan view showing a pattern formed on a substrate in accordance with the photomask of FIG. 2.

### DETAILED DESCRIPTION OF THE PREFERRED EMBODIMENTS

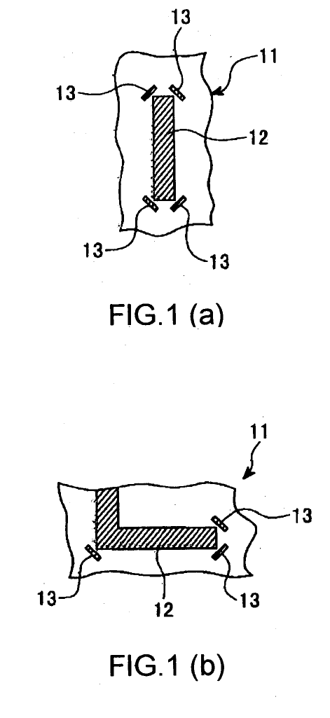

FIGS. 1 (a) & (b) are plan views that show the main parts of a photomask of a basic embodiment of the present invention. The photomask is a reticle 11. The reticle 11 has a pattern 12 for forming an element and an integrated circuit on a semiconductor wafer. The reticle 11 is also provided with at least an auxiliary pattern 13 that corrects line degeneration resulting from the effects of exposure, thereby functioning effectively to improve the resolution of a resist (positive resist) pattern for forming microscopic elements.

In this embodiment, a bar-shaped auxiliary pattern that corrects line degradation is provided for a line that runs in the X direction or Y direction in a pattern. The auxiliary pattern is disposed near the end of the line or near the outside corner of the line where it changes direction. Moreover, the auxiliary pattern is placed oblique to both the X and the Y directions. The auxiliary patterns 13 are in the shape of a bar of a prescribed length that is preferably arranged at a uniform angle (approximately 45 degrees diagonal) to both the X and Y directions. The auxiliary patterns 13 are arranged in locations separated by a prescribed distance from the outside corners of lines requiring degeneration correction.

According to a photomask of the aforementioned embodiment, by providing the auxiliary pattern 13, it is possible to correct degeneration of at least line the corner areas of lines in an actual exposure pattern. In other words, the auxiliary pattern can function as an optical proximity correction mask.

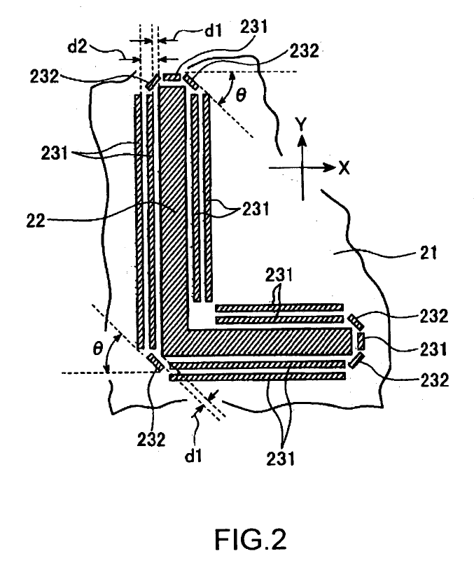

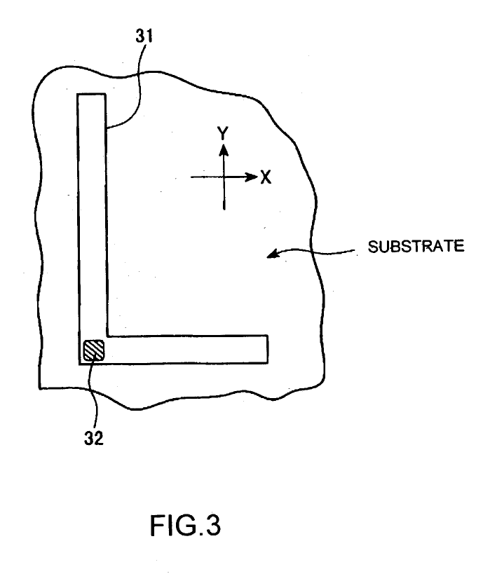

FIG. 2 is a plan view showing the main parts of a photomask according to a preferred embodiment of the present invention. FIG. 3 is a plan view showing a resist (positive resist) pattern formed on a substrate in accordance with the photomask of FIG. 2. In addition, the shaded portion in FIG. 3 indicates the contact area. The dotted line portion indicates an example of line degeneration in the event that the auxiliary pattern is not placed on the photomask.

In FIG. 2, the reticle 21 used as a photomask has a pattern 22 for forming an element and an integrated circuit on a semiconductor wafer. The reticle 21 is also provided with at least auxiliary patterns 231, 232 that correct line degeneration caused by the effects of exposure. Preferably, the respective linewidths of auxiliary patterns 231, 232 are ⅓ to ¼ of the line widths of the pattern 22. Hence, they effectively function is to improve the resolution of patterns of microscopic lines. In other words, as an optical proximity correction mask, this photomask includes a technique for correcting the degeneration of lines in a pattern at the time of exposure.

The auxiliary patterns 231 are parallel assist bars that run in the X direction or the Y direction, separated by a prescribed distance d1 (or d2) from lines that run in the X direction or Y direction in the pattern 22. The auxiliary patterns 231, which mainly correct degeneration in the width direction of a line, particularly control the infiltration of light during exposure into areas where lines are not densely clustered together, thereby preventing undesirable line width narrowing. FIG. 2 shows a double pattern configuration wherein the auxiliary patterns 231 are also disposed in locations separated from the line by a prescribed distance d2. However, the auxiliary pattern configuration is not limited to this and, depending on the density with which the lines are packed, the auxiliary patterns may be disposed as two or more lines or as a single line. In addition, the auxiliary patterns 231 disposed in the X direction or Y direction at the end of the lines may be absent.

Auxiliary patterns 232 are disposed with respect to a line that runs in the X direction or Y direction in the pattern 22, the auxiliary pattern being disposed near the end of a line or near the outside corner of a line that changes direction. Preferably, the auxiliary patterns 232 are an assist bar of a prescribed length that extends in a direction whose angle θ with respect to both the X and Y directions is an approximately oblique 45 degrees. Furthermore, the auxiliary patterns 232 are disposed in a location that is separated by a prescribed distance with respect to corners requiring degeneration correction. This prescribed distance is, for example, the distance at which the distance along a line perpendicular to the auxiliary patterns 232 become d1. This line is in the direction approximately bisecting an angle at the outer edge of the corner.

According to the photomask of the aforementioned embodiment, by providing auxiliary patterns 231,232, it is possible to correct the degeneration of at least line width and line corner members in an actual exposure pattern. In other words, the photomask of the embodiment can function as an optical proximity correction mask.

A method for producing a pattern in the aforementioned configuration is explained below. This pattern is formed with the same design rules as the main data of the reticle carrying the pattern (mask pattern) for wiring needed to form an element and integrated circuit. In other words, depending on the information for a line that runs along either the X direction or Y direction, an assist bar (auxiliary pattern 231) is disposed as a pattern for correcting optical proximity effects in a mask pattern. Moreover, the assist bar is separated from the line by a prescribed distance (d1 or d2) and is parallel to the X director or Y direction. Conforming to this pattern description, a further patternized processing is added to a line that runs along the X direction or Y direction in a mask pattern, depending on the information for the end or corner where there is a change of direction. In this processing, an assist bar (auxiliary pattern 232) that serves as a pattern for correcting optical proximity effects is disposed in a region separated by a prescribed distance (d1) from the outside corner of the line and has a specific oblique angle of 45 degrees with respect to the X and Y directions.

According to a method of producing a mask pattern of the present invention, each specific bar-shaped pattern is formed as an assist bar. In other words, as an auxiliary pattern 231 is disposed parallel to a line, an identical auxiliary pattern 232 is automatically arranged to the outside of any of the corners, each in a region separated by a prescribed distance. Hence, the formation of auxiliary patterns to counter corner degeneration is expeditiously achieved with a small amount of information. Furthermore, in regions where lines are densely clustered together, a parallel auxiliary pattern 231 cannot be formed, nor can a corner auxiliary pattern 232 be automatically disposed. However, it is conceivable in some cases that the auxiliary pattern 232 may be disposed independently in a corner.

A photomask of the aforesaid configuration exhibits a particular effect in the formation of the fine wiring in an integrated circuit.

As shown in FIG. 3, when realizing a resist (positive resist) pattern 31 using photolithography, the shape of corners in particular are improved as miniaturization progresses. In other words, degeneration such as that indicated by the dashed line can be prevented, contributing especially to improved reliability when, for example, later forming a contact pattern in a corner area such as in the shaded area 32. Hence, the shape of a corner is also improved in the miniaturized elements and integrated circuit patterns formed on a substrate, and a semiconductor device having improved reliability of contact patterns for wiring can be formed.

Moreover, in the aforementioned embodiment, the use of an optical proximity correction mask was described as an example of a technique for correcting line degeneration. However, the present invention is not limited to an optical proximity correction mask but can also be used in a photomask (for example, a phase shift mask) that can correct line degeneration using a different technique.

As described above, according to a photomask of the present invention, an auxiliary pattern that has patternized information of a bar shape in an oblique direction contributes at least to the correction of line degeneration in an actual exposure pattern, so as to effectively correct the degeneration of at least line ends and corners where a line changes direction. As a result, the degeneration of lines in a fine exposure pattern can easily be corrected, and a photomask, a pattern production method, and a semiconductor element that improve reliability can be provided.

What is claimed is:

1. A photomask for transferring a pattern comprising:
a predetermined line arranged in a pattern; and
at least one bar-shaped auxiliary pattern for correcting line degeneration disposed at least near an end of the predetermined line or near an outside corner of the predetermined line and arranged in an oblique direction that differs from the direction of the predetermined line.

2. A photomask for transferring a pattern comprising:
a predetermined line running in the X direction or Y direction in a pattern;
a bar-shaped first auxiliary pattern for correcting line degeneration, separated by a prescribed distance from the predetermined line and parallel to the X direction or Y direction; and
a bar-shaped second auxiliary pattern for correcting line degeneration, oblique to both the X and Y directions, disposed near an end of the predetermined line or near an outside corner where a direction of the predetermined line changes.

3. The photomask according to claim 2, wherein the first auxiliary pattern or the second auxiliary pattern is a bar shape of a prescribed length located in a direction of an angle of approximately 45 degrees with respect to both the X and the Y directions.

4. A method for producing a pattern for a photomask comprising:
forming a predetermined line running in the X direction or Y direction in a pattern; and
disposing a first bar-shaped pattern as a pattern for optical proximity effects correction in a direction of a specific angle with respect to both the X and the Y directions and, in response to information for an end of the predetermined line or a corner where a direction of the predetermined line changes, in a region separated by a prescribed distance from the corner.

5. The method for producing a pattern according to claim 4, further comprising disposing a second bar-shaped pattern that serves as a pattern for correcting optical proximity effects in the pattern such that the second bar-shaped pattern is parallel to the X direction or the Y direction, depending on information for the predetermined line, but separated by a prescribed distance from the predetermined line.

6. A semiconductor device comprising an element and an integrated circuit pattern, which are formed on a substrate by using a photomask according to claim 1.

7. The photomask according to claim 1, wherein the photomask is a reticle.

8. The photomask according to claim 1, wherein the reticle has a pattern for forming an integrated circuit on a semiconductor wafer.

9. The photomask according to claim 2, wherein the photomask is a reticle.

10. The photomask according to claim 2, wherein the reticle has a pattern for forming an integrated circuit on a semiconductor wafer.

11. The photomask according to claim 1 wherein the bar-shaped auxiliary pattern has a prescribed length located in a direction of an angle of approximately 45 degrees with respect to both the X and Y directions.

12. The photomask according to claim 1, wherein the bar-shaped auxiliary pattern operates as an optical proximity correction mask.

13. The photomask according to claim 2, wherein the bar-shaped first auxiliary pattern and the bar-shaped second auxiliary pattern operate as an optical proximity correction mask.

14. The photomask according to claim 1, wherein bar-shaped auxiliary pattern has a line width of ⅓ of that of the predetermined line.

15. The photomask according to claim 1, wherein the bar-shaped auxiliary pattern has a line width of ¼ of that of the predetermined line.

16. The photomask according to claim 2, wherein the bar-shaped first auxiliary pattern has a line width of ⅓ of that of the predetermined line.

17. The photomask according to claim 2, wherein the bar-shaped second auxiliary pattern has a line width of ¼ of that of the predetermined line.

18. The method according to claim 4, further providing forming an integrated circuit on a semiconductor wafer.

19. The method according to claim 4, further comprising operating the first bar-shaped pattern as an optical proximity correction mask.

20. The method according to claim 4 further comprising forming the first bar-shaped pattern to have a width of ⅓ of that of the predetermined line.
